(19) United States
(12) Patent Application Publication
(10) Pub. No.: US 2026/0136917 A1
(43) Pub. Date: May 14, 2026

(54) Tapered Connectors for Superconductor Circuits

(71) Applicant: PsiQuantum Corp., Palo Alto, CA (US)

(72) Inventors: Faraz Najafi, San Francisco, CA (US); Vitor R. Manfrinato, San Jose, CA (US)

(21) Appl. No.: 18/957,060

(22) Filed: Nov. 22, 2024

Related U.S. Application Data
(63) Continuation of application No. 18/518,394, filed on Nov. 22, 2023, now Pat. No. 12,199,039.
Application No. 18/518,394 is a continuation of application No. 17/408,309, filed on Aug. 20, 2021, now Pat. No. 11,830,811.
Application No. 17/408,309 is a continuation of application No. 16/575,274, filed on Sep. 18, 2019, now Pat. No. 11,101,215.
(60) Provisional application No. 62/733,553, filed on Sep. 19, 2018.

(51) Int. Cl. H10W 20/41; H10N 60/83; H10N 60/84; H10N 60/85; H10N 69/00; H10W 20/44

(52) U.S. Cl. CPC H10W 20/435; H10N 60/83; H10N 69/00; H10N 60/84; H10N 60/855; H10W 20/4484

(57) ABSTRACT

An example superconducting circuit includes a first component having a first end with a first width and a second component having a second end with a second width, the second width different than the first width. The example circuit further includes an asymmetrically-tapered connector electrically connected to the first end of the first component with the second end of the second component, the asymmetrically-tapered connector comprising a set of asymmetrical tapered portions.

### RELATED AND PRIORITY APPLICATIONS

This application is a continuation of U.S. application Ser. No. 18/518,394, filed Nov. 22, 2023, which is a continuation of U.S. application Ser. No. 17/408,309, filed Aug. 20, 2021, now U.S. Pat. No. 11,830,811, which is a continuation of U.S. application Ser. No. 16/575,274, filed Sep. 18, 2019, now U.S. Pat. No. 11,101,215, which claims priority to U.S. Provisional Patent Application 62/733,553, entitled “Tapered Connectors for Superconductor Circuits,” filed Sep. 19, 2018, each of which is hereby incorporated by reference in its entirety.

### TECHNICAL FIELD

This relates generally to superconducting circuits, including but not limited to, tapered connectors for superconducting circuits.

### BACKGROUND

Superconductors are materials capable of operating in a superconducting state with zero electrical resistance under particular conditions. One parameter for operating in a superconducting state is current density. If current density exceeds a superconducting threshold density the superconductor will operate in a non-superconducting state. Geometric shapes such as corners may lead to current crowding effects that result in the current density exceeding the superconducting threshold density at some locations. Moreover, mathematically-optimal tapered connectors can be hard to manufacture.

### SUMMARY

There is a need for circuits and devices with more efficient and effective methods for reducing or minimizing current crowding in manufactured superconductors. Such circuits, devices, and methods optionally complement or replace conventional systems, devices, and methods for reducing or minimizing current crowding effects.

In one aspect, some embodiments include a superconducting circuit. The superconducting circuit includes: (1) a first component having a first connection point (e.g., a terminal), the first connection point having a first width; (2) a second component having a second connection point, the second connection point having a second width that is larger than the first width; and (3) a connector electrically connecting the first connection point and the second connection point, the connector including: (a) a first taper having a first slope and a non-linear shape; (b) a second taper having a second slope; and (c) a connecting portion connecting the first taper to the second taper, the connecting portion having a third slope that is less than the first slope and less than the second slope.

In another aspect, some embodiments include a superconducting circuit that includes: (1) a first component having a first connection point, the first connection point having a first width; (2) a second component having a second connection point, the second connection point having a second width that is larger than the first width; and (3) a connector electrically connecting the first connection point and the second connection point, the connector including: (a) a first taper positioned adjacent the first connection point and having a non-linear shape; and (b) a second taper positioned adjacent the second connection point and having a linear shape.

In another aspect, some embodiments include a superconducting component that includes: (1) a first portion having a first width; (2) a second portion having a second width; (3) a curved portion coupling the first portion and the second portion, wherein the curved portion has a third width that is at least three times greater than the first width and at least three times greater than the second width; and (4) tapered portions connecting the curved portion to the first portion and the second portion.

In yet another aspect, some embodiments include a superconducting circuit that include: (1) a first component having a first connection point, the first connection point having a first width; (2) a second component having a second connection point, the second connection point having a second width that is larger than the first width; and (3) a connector electrically connecting the first connection point and the second connection point, the connector comprising a tapered portion shaped to minimize current crowding effects, the tapering defined by a taper formula meeting certain current crowding reduction criteria and elongated by a preset factor.

Thus, devices and circuits are provided with methods for reducing or minimizing current crowding by use of tapered connectors, thereby increasing the effectiveness, efficiency, and user satisfaction with such circuits and devices.

### BRIEF DESCRIPTION OF THE DRAWINGS

For a better understanding of the various described embodiments, reference should be made to the Detailed Description below, in conjunction with the following drawings in which like reference numerals refer to corresponding parts throughout the figures.

FIGS. 1A-1D are diagrams illustrating representative connectors in accordance with some embodiments.

FIG. 2 is a diagram illustrating another representative connector in accordance with some embodiments.

FIG. 3 is a diagram illustrating a representative circuit in accordance with some embodiments.

FIGS. 4A-4B are diagrams illustrating representative connectors in accordance with some embodiments.

FIGS. 5A-5C are diagrams illustrating representative connectors in accordance with some embodiments.

### DETAILED DESCRIPTION

Reference will now be made in detail to embodiments, examples of which are illustrated in the accompanying drawings. In the following detailed description, numerous specific details are set forth in order to provide a thorough understanding of the various described embodiments. However, it will be apparent to one of ordinary skill in the art that the various described embodiments may be practiced without these specific details. In other instances, well-known methods, procedures, components, circuits, and networks have not been described in detail so as not to unnecessarily obscure aspects of the embodiments.

Many modifications and variations of this disclosure can be made without departing from its spirit and scope, as will be apparent to those skilled in the art. The specific embodiments described herein are offered by way of example only, and the disclosure is to be limited only by the terms of the appended claims, along with the full scope of equivalents to which such claims are entitled.

A threshold superconducting current for a superconductor component is dependent on current density within the superconductor component. Current crowding effects at corners or curves lead to increased current density, which in turn leads to a lower threshold superconducting current. Therefore, it is important to shape the superconductor component to reduce or minimize current crowding effects (e.g., through the use of tapered connectors).

Mathematically-optimal tapers can minimize current crowding in superconductor devices. However, mathematically-optimal tapers can be difficult to manufacture in some circumstances, such as with superconductor devices having width(s) that are less than 1 micron. For example, drift during an e-beam process leads to stepping of a mathematically-optimal curve, which increases current crowding effects. As another example, a lithography process may over-expose or under-expose parts of a steep curve, which also increase current crowding effects. The present disclosure describes superconducting tapers that both prevent current crowding and are manufacturable.

Equations (1)-(3) below are examples of curves that meet certain current crowding reduction criteria (e.g., are mathematically-optimal curves). Equation (1) defines a curve along the x-axis and y-axis for a component with a 90-degree turn.

$$Curve for 90 - degree Turn \qquad Equation 1$$

$${y}_{90} ( x ) = W \{ 1 + \frac{2}{π} {sinh}^{- 1} [ \frac{1}{sinh [ ( π / 2 W ) ( x - W ) ]} ] \}$$

In Equation (1) above, W is the width of the component prior to (e.g., outside, but adjacent to) the turn (e.g., a straight portion of the component). Equation (2) defines a curve along the x-axis and y-axis for a component with a 180-degree turn (e.g., a u-shaped turn).

$$Curve for 180 - degree Turn \qquad Equation 2$$

$${y}_{180} ( x ) = \pm ( 2 W / π ) {cos}^{- 1} [ exp ( π x / 2 W ) / 2 ]$$

In Equation (2) above, W is the width of the component prior to (e.g., outside, but adjacent to) the turn. Equation (3) shows a complex-number function zeta, ζ(c), indicating a curve along the x-axis and y-axis for a tapered component.

$$Complex - number Function for Tapered Portion$$

$$ζ ( c ) = \frac{i}{π} [ W {tan}^{- 1} ( \frac{\sqrt{c ( α ) - γ}}{\sqrt{γ + 1}} ) + A {tan}^{- 1} ( \frac{\sqrt{γ - 1}}{\sqrt{c ( α ) - γ}} ) ]$$

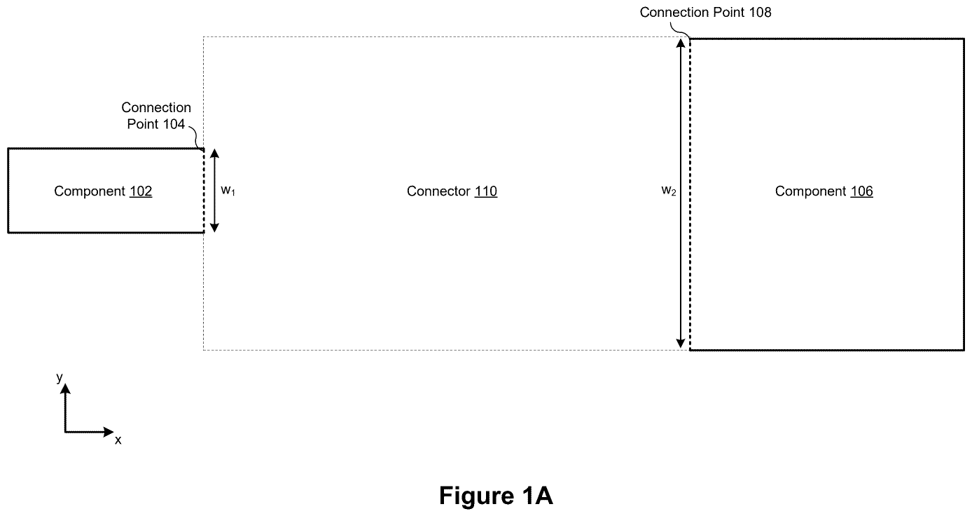

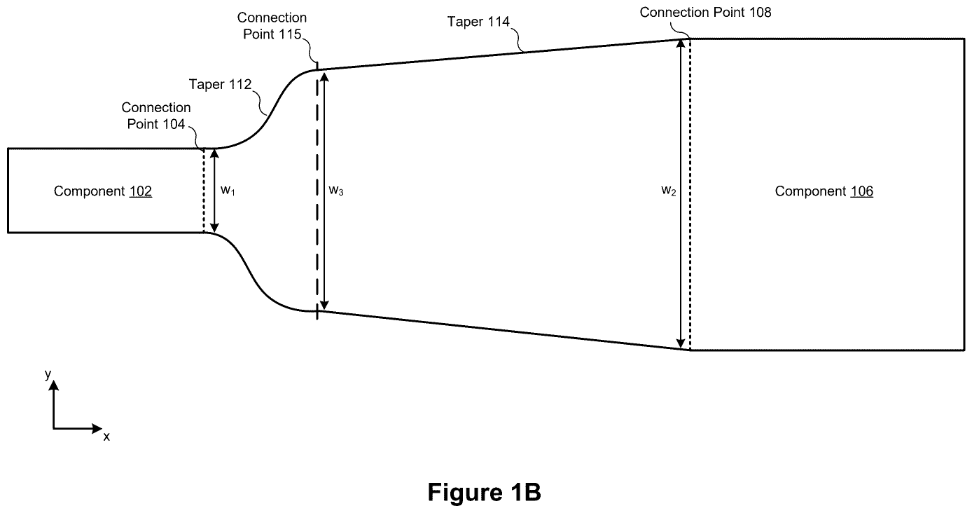

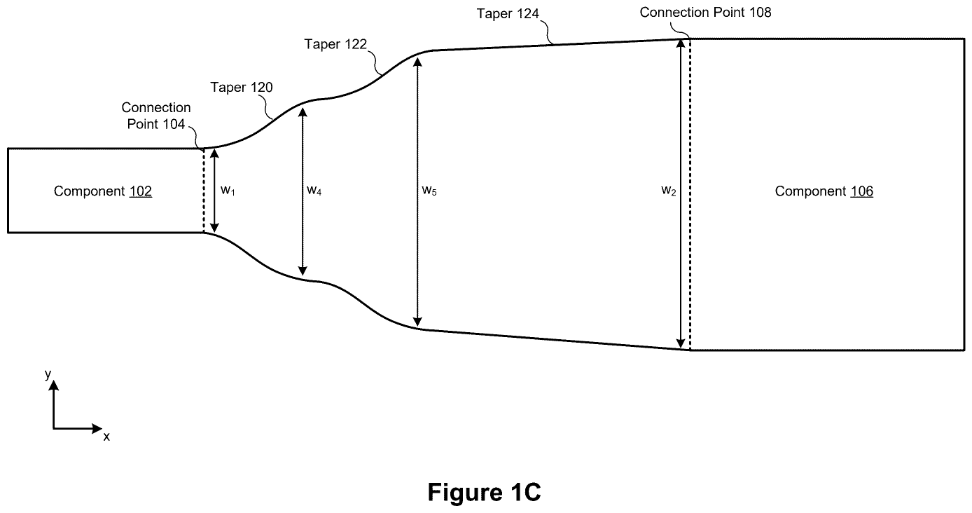

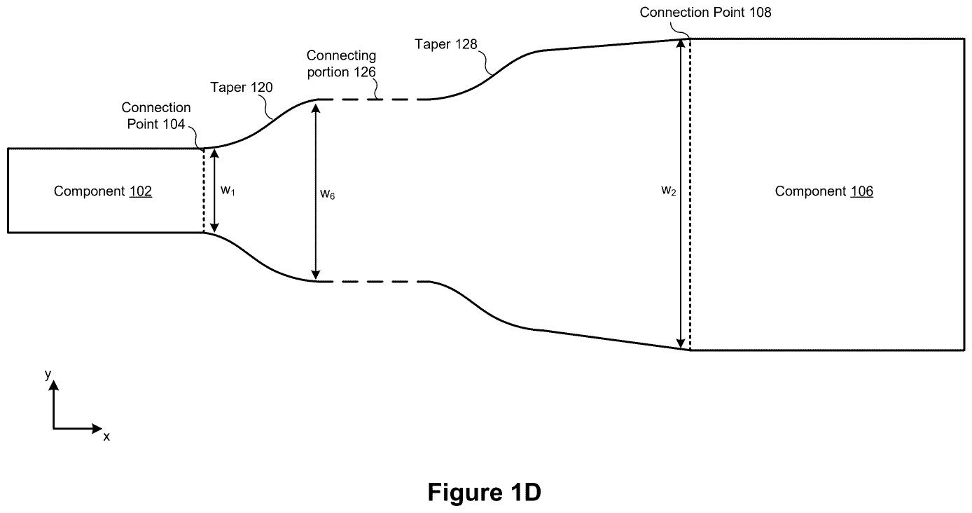

In Equation (3) above, W is the width of the narrow end of the tapered portion (e.g., w₁ in FIG. 1A), A is the width of the wider end of the tapered portion (e.g., w₂ in FIG. 1A), gamma (γ) is defined by Equation (4), and c(α) is defined by Equation (5).

$$Relationship Between Wide and Narrow Ends \qquad Equation 4$$

$$γ = \frac{( {A}^{2} + {W}^{2} )}{( {A}^{2} - {W}^{2} )}$$

$$Angle Mapping \qquad Equation 5$$

$$c ( α ) = cos ( α ) + i sin ( α )$$

As the angle α in Equation (5) is varied from 0 to π, the x and y coordinates for a curved boundary of the tapered portion can be obtained via Equations (6) and (7) below.

$$X - coordinate of Curved Boundary \qquad Equation 6$$

$$x ( α ) = Re ( ζ ( α ) )$$

$$Y - coordinate of Curved Boundary \qquad Equation 7$$

$$y ( α ) = Im ( ζ ( α ) )$$

As shown in Equations (6) and (7) above, the x-coordinate is obtained from the real portion of the function zeta and the y-coordinate is obtained from the imaginary portion of the function zeta.

FIGS. 1A-1D are diagrams illustrating representative connectors in accordance with some embodiments. FIG. 1A shows a first component, labeled component 102, and a second component, component 106, coupled by connector 110 in accordance with some embodiments. Component 102 has a connection point, connection point 104, with a first width, w₁. Component 106 has a connection point, connection point 108, with a second width, w₂. As shown in FIG. 1A, w₂ is greater than w₁. In some embodiments, connector 110 is adapted to reduce current crowding within the connector. In some embodiments, the first component, the second component, and the connector are arranged on a same layer of superconducting material. In some embodiments, the first component, the second component, and the connector are composed of a same material (e.g., a superconducting material such as NbGe or NbN). In some embodiments, the first and second components and the connector are formed via etching of a superconducting film. In some embodiments, the first component is a photon detector (e.g., an SNSPD). In some embodiments, the second component is a pad or via. In some embodiments, the first or second component is an inductor or resistor.

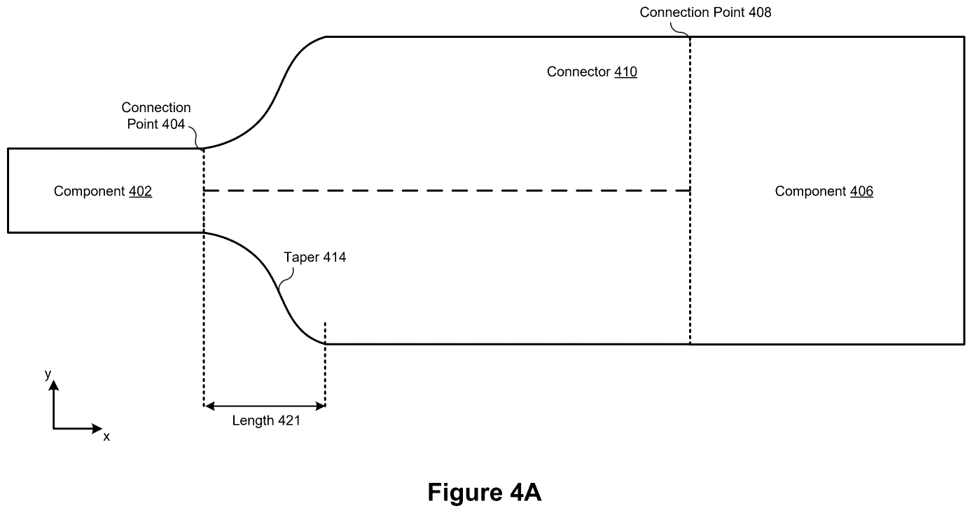

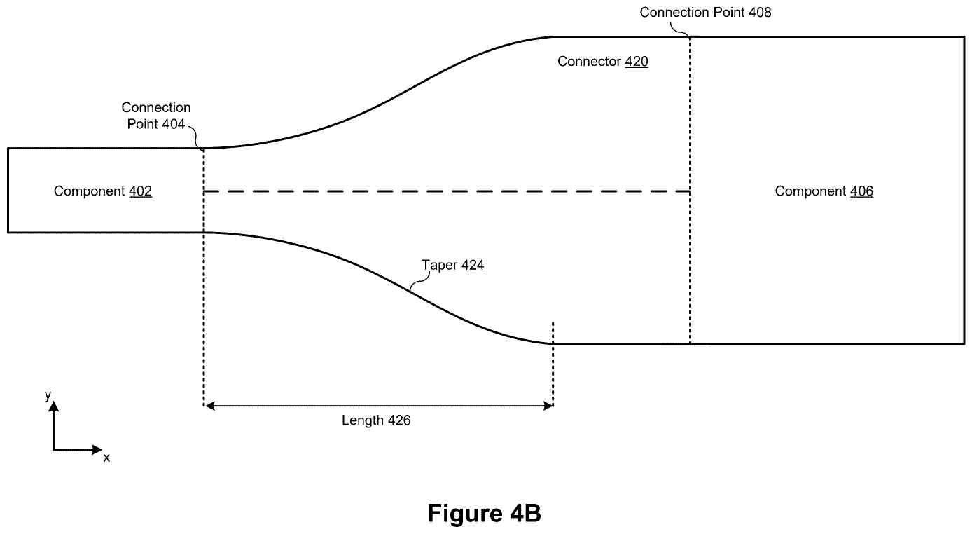

In various embodiments, connector 110 has various tapered shapes to reduce or minimize current crowding effects as current flows between component 102 and component 106. In some embodiments, if the ratio of w₂ to w₁ is less than a preset factor (e.g., 3, 4, or 5, or more generally a predefined value between 2.5 and 5), connector 110 has a tapered shape meeting one or more current crowding reduction criteria (e.g., mathematically-optimal tapered shape), such as the tapered shape set forth in Equations (3)-(7) above. In some embodiments, if the ratio of w₂ to w₁ is greater than the preset factor, connector 110 includes a series of tapers (e.g., FIGS. 1B-1D), or a tapered shape that is elongated from a tapered shape meeting one or more current crowding reduction criteria (e.g., mathematically-optimal tapered shape), such as the tapered shape set forth in Equations (3)-(7) above (e.g., the elongated tapered shape shown in FIG. 4B). In some embodiments, each taper is a tapered region of superconducting material having two ends, each end of the tapered region having a distinct width. In some embodiments, the tapers of connector 110 (e.g., the tapers shown in FIGS. 1B-1D) are shaped so as to reduce current crowding within the connector. In some embodiments, the tapers of connector 110 (e.g., the tapers shown in FIGS. 1B-1D) are adapted (e.g., designed) based on a lithography process used to form the connector. In some embodiments, connector 110 includes multiple tapered regions and the tapered regions have respective first derivatives that are matched at connection points of the tapered regions.

FIG. 1B shows connector 110 as a set of tapered elements, taper 112 and taper 114, connected at connection point 115 in accordance with some embodiments. As shown in FIG. 1B, taper 112 is a non-linear taper (e.g., the tapered shape set forth in Equations (3)-(7) above) decreasing from an intermediate width w₃ to the width, w₁, of connection point 104. Taper 114 is a linear taper (e.g., has linear boundaries) decreasing from the width, w₂, of connection point 108 to the intermediate width w₃. In some embodiments, taper 112 and taper 114 have a same first derivative at connection point 115 (e.g., are slope-matched at the connection point). In some embodiments, a first taper (e.g., the taper 112) narrows from an intermediate width w₃ to a first width w₁, and the intermediate width is less than five times the first width. In some embodiments, the intermediate width (IW) and first width (FW), satisfy the following: 3*FW≤IW<5*FW. Alternatively, in some embodiments, the intermediate width (IW) and first width (FW), satisfy the following: 2*FW≤IW<5*FW.

FIG. 1C shows connector 110 as another set of tapered elements, taper 120, taper 122, and taper 124, in accordance with some embodiments. As shown in FIG. 1C, taper 120 is a non-linear taper (e.g., the tapered shape set forth in Equations (3)-(7) above) decreasing from an intermediate width w₄ to the width, w₁, of connection point 104. Taper 122 is a non-linear taper (e.g., the tapered shape set forth in Equations (3)-(7) above) decreasing from a second intermediate width w₅ to the intermediate width w₄. Taper 124 is a linear taper decreasing from the width, w₂, of connection point 108 to the intermediate width w₅.

FIG. 1D shows connector 110 as a set of tapered elements, taper 120 and taper 128, connected via a connecting portion 126 in accordance with some embodiments. As shown in FIG. 1D, taper 120 is a non-linear taper (e.g., the tapered shape set forth in Equations (3)-(7) above) decreasing from an intermediate width w₆ to the width, w₁, of connection point 104. Taper 128 is a non-linear taper decreasing from the width, w₂, of connection point 108 to the intermediate width w₆. Connecting portion 126 is a portion of connector 110 having a slope less than the slopes of tapers 120 and 128 (e.g., the connecting portion 126 has a slope of zero and each of tapers 120 and 128 includes a portion having a slope greater than zero). More generally, connection portion 126 need not be linear, but includes a portion having a slope (e.g., typically, but not necessarily having a slope of zero) that is less than a slope (e.g., a maximum slope of at least a portion of) of the tapers to which it is connected.

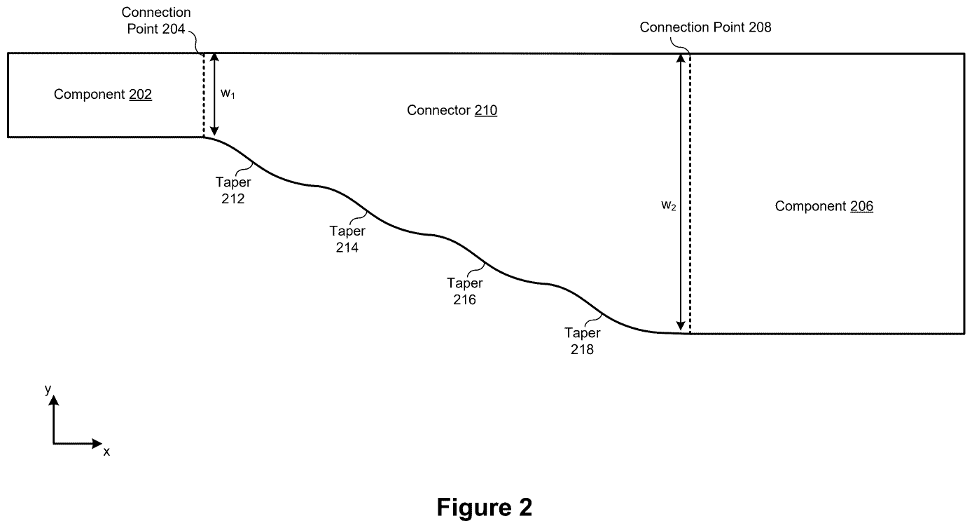

FIG. 2 is a diagram illustrating connector 210 in accordance with some embodiments. FIG. 2 shows a first component, labeled component 202, and a second component, component 206, coupled by connector 210 in accordance with some embodiments. Component 202 has a connection point, connection point 204, with a first width, w₁. Component 206 has a connection point, connection point 208, with a second width, w₂. As shown in FIG. 2, w₂ is greater than w₁. FIG. 2 also shows connector 210 as a set of asymmetrical tapered portions, tapers 212, 214, 216, and 218. In accordance with some embodiments, the tapered portions are slope-matched at the respective connection points to reduce (e.g., minimize) current crowding effects.

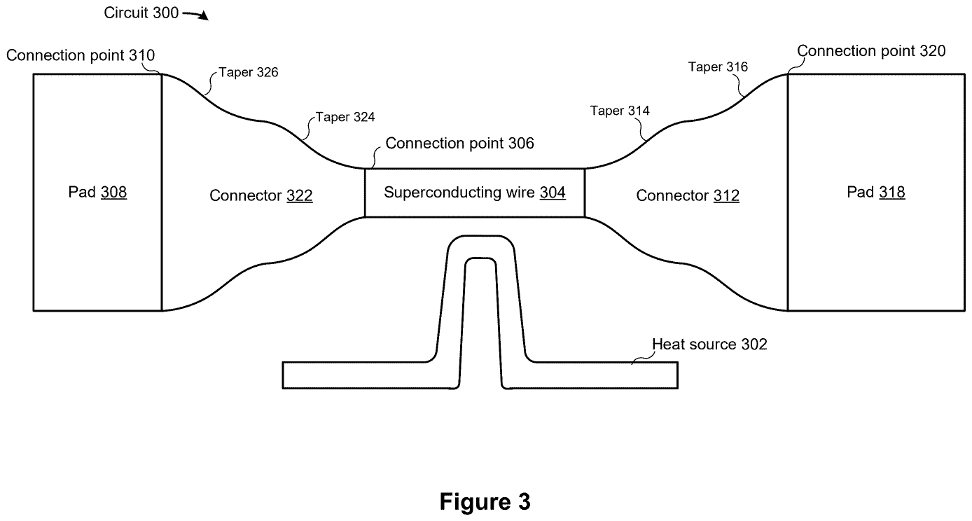

FIG. 3 is a diagram illustrating circuit 300 in accordance with some embodiments. FIG. 3 shows a superconducting wire 304 electrically-connected to pads 308 and 318 via tapered connectors 322 and 312. Tapered connector 312 (which includes tapers 314 and 316) is connected to pad 318 at connection point 320. Tapered connecter 322 (which includes tapers 324 and 326) is connected to pad 308 at connection point 310. Tapered connector 322 is further connected to superconducting wire 304 at connection point 306. FIG. 3 also shows a heat source 302 (e.g., a superconductor, conductor, or semiconductor) thermally-coupled to superconducting wire 304. In accordance with some embodiments, heat source 302 selectively generates heat to transition superconducting wire 304 from a superconducting state to a non-superconducting state. In accordance with some embodiments, a current source (not shown) is electrically-coupled to one of pads 318 and 308 such that current flows between pads 318 and 308 through superconducting wire 304. In accordance with some embodiments, a readout component (not shown) is electrically-coupled to one of pads 318 and 308 and configured to determine a state of superconducting wire 304 (e.g., based on an amount of current received at the readout component). In some embodiments, one or more additional components (not shown) are coupled between pads 318 and 308, such as an inductor, a resistor, or a capacitor.

FIGS. 4A-4B are diagrams illustrating representative connectors in accordance with some embodiments. FIG. 4A shows a connector 410 (which connects component 406 at connection point 408 to component 402 at connection point 404) having a tapered portion 414 with a first length 421. FIG. 4B shows a connector 420 having a tapered portion 424 with a second length 426. In accordance with some embodiments, tapered portion 414 utilizes a taper shaped in accordance with Equations (3)-(7) and tapered portion 424 utilizes an elongated version of taper 414 (e.g., elongated in accordance with Equation (8) below), such that length 426 is greater than length 421 and a maximum slope of tapered portion 414 is greater than a maximum slope of tapered portion 424. Equation (8) below shows an elongation factor to be applied to a mathematically-defined tapered shape (e.g., the tapered shape defined in Equations (3)-(7) above).

$$Elongation Factor \qquad Equation 8$$

$$α = \frac{( Δ x * m ) + L}{L}$$

In Equation (8) Δx is a displacement value due to drift during a fabrication process, m is a constant (e.g., a constant in the range of 5 to 10), and L is a length of the mathematically-defined tapered shape.

As discussed previously, reducing a maximum slope of the tapered portions reduces the impact of lithography inaccuracies in some circumstances. Moreover, a vertically-symmetric taper, as shown in FIG. 4B, reduces a current crowding impact of vertical drift during a lithography process for the connector.

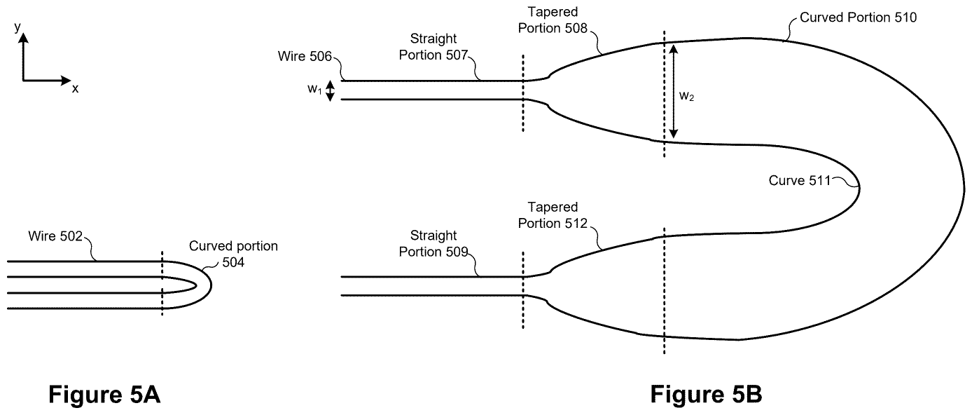

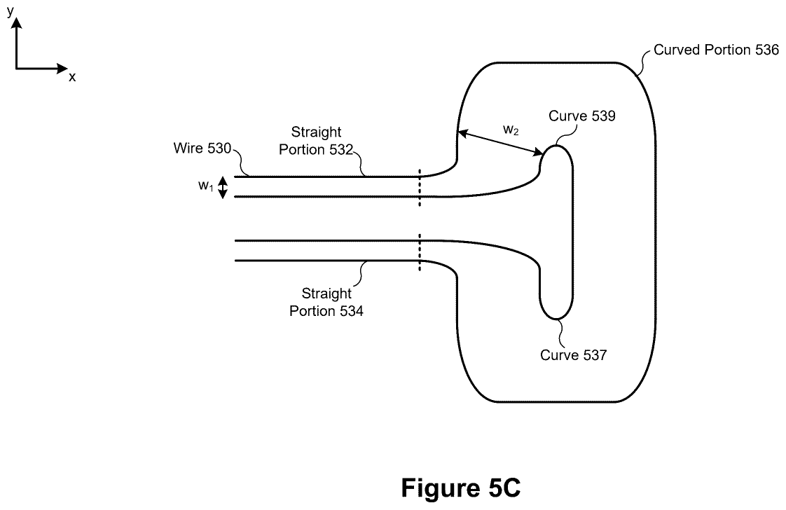

FIGS. 5A-5C are diagrams illustrating representative connectors in accordance with some embodiments. FIG. 5A shows wire 502 including a curved portion 504 (e.g., a u-shaped curved portion). Wire 502 in FIG. 5A has a substantially same width throughout (e.g., within 5%, 10%, 20% of the same width), and thus suffers from current crowding within the curved portion 504 in some circumstances.

FIG. 5B shows a wire 506 having straight portions 507 and 509 coupled to a curved portion 510 via tapered portions 508 and 512 respectively. FIG. 5B shows straight portion 507 having a width w₁ and curved portion 510 having a width w₂ that is greater than w₁. In some embodiments, the inner curve of curved portion 510 is shaped in accordance with Equation (2) above. In some embodiments, the ratio of w₂ to w₁ is in the range of 3 to 5. In some embodiments, the ratio of w₂ to w₁ is greater than 3 and the tapered portions 508 and 512 each include a series of tapered portions (e.g., similar to those shown in FIGS. 1B-1D). In some circumstances, having the width w₂ be greater than the width w₁ decreases current crowding effects in the wire 506 (e.g., as compared to current crowding effects in the wire 502). In some embodiments, straight portions 507 and 509 are substantially parallel (e.g., within 5 degrees, 10 degrees, or 20 degrees of parallel). In some embodiments, straight portions 507 and 509 are each linear in shape (e.g., have linear boundaries). In some embodiments, curved portion 510 is u-shaped (e.g., turns 180 degrees). In some embodiments, curved portion 510 includes a first end and a second end, opposite the first end; and the first end and the second end are substantially parallel (e.g., within 5 degrees, 10 degrees, or 20 degrees of parallel). In some embodiments, curved portion 510 is shaped to reduce or minimize current crowding effects (e.g., curve 511 is shaped in accordance with Equation (2)). In some embodiments, tapered portions 508 and 512 are shaped to reduce or minimize current crowding effects in the tapered portions. In some embodiments, tapered portions 508 and 512 are shaped to also reduce (e.g., minimize) current crowding effects in curved portion 510. In some embodiments, tapered portions 508 and 512 are non-linear in shape (e.g., are shaped in accordance with Equations (3)-(7) above).

FIG. 5C shows a wire 530 having straight portions 532 and 534 in close proximity to one another, e.g., close enough that there is insufficient space to utilize the curved portion 510 of FIG. 5B. FIG. 5C also shows straight portions 532 and 534 coupled to one another via curved portion 536. In some embodiments, inner curves 537 and 539 of curved portion 536 are shaped in accordance with Equation (2). As shown in FIG. 5C the curved portion 536 has a width w₂, that is greater than w₁, and includes tapered portions (e.g., shaped in accordance with Equations (3)-(7) above) to reduce or minimize current crowding in wire 530. In some embodiments, the ratio of w₂ to w₁ is in the range of 3 to 5. In some circumstances, having the width w₂ be greater than the width w₁ decreases current crowding effects in the wire 530 (e.g., as compared to current crowding effects in the wire 502 of FIG. 5A).

It will also be understood that, although the terms first, second, etc. are, in some instances, used herein to describe various elements, these elements should not be limited by these terms. These terms are only used to distinguish one element from another. For example, a first current could be termed a second current, and, similarly, a second current could be termed a first current, without departing from the scope of the various described embodiments. The first current and the second current are both currents, but they are not the same condition unless explicitly stated as such.

The terminology used in the description of the various described embodiments herein is for the purpose of describing particular embodiments only and is not intended to be limiting. As used in the description of the various described embodiments and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein, a “superconducting circuit” or “superconductor circuit” is a circuit having one or more superconducting materials. For example, a superconductor switch circuit is a switch circuit that includes one or more superconducting materials. As used herein, a “superconducting” material is a material that is capable of operating in a superconducting state (under particular conditions). For example, a superconducting material is a material that operates as a superconductor (e.g., operates with zero electrical resistance) when cooled below a particular temperature (e.g., a threshold temperature) and having less than a threshold current flowing through it. A superconducting material is also sometimes called herein a superconduction-capable material. In some embodiments, the superconducting materials operate in an “off” state where little or no current is present. In some embodiments, the superconducting materials can operate in a non-superconducting state during which the materials have a non-zero electrical resistance (e.g., a resistance in the range of one thousand to ten thousand ohms). For example, a superconducting material supplied with a current greater than a threshold superconducting current for the superconducting material transitions from a superconducting state having zero electrical resistance to a non-superconducting state having non-zero electrical resistance.

As used herein, a “wire” is a section of material configured for transferring electrical current. In some embodiments, a wire includes a section of material conditionally capable of transferring electrical current. For example, a wire made of a superconducting material that is capable of transferring electrical current while the wire is maintained at a temperature below a threshold temperature. As another example, a wire made of semiconducting material is capable of transferring electrical current while the wire is maintained at a temperature above a freeze-out temperature. A cross-section of a wire (e.g., a cross-section that is perpendicular to a length of the wire) optionally has a regular (e.g., flat or round) shape or an irregular shape. While some of the figures show wires having rectangular shapes, any shape could be used. In some embodiments, a length of a wire is greater than a width or a thickness of the wire (e.g., the length of a wire is at least 5, 6, 7, 8, 9, or 10 times greater than the width and the thickness of the wire). In some cases, a wire is a section of a superconducting layer.

The foregoing description, for purpose of explanation, has been described with reference to specific embodiments. However, the illustrative discussions above are not intended to be exhaustive or to limit the scope of the claims to the precise forms disclosed. Many modifications and variations are possible in view of the above teachings. The embodiments were chosen in order to best explain the principles underlying the claims and their practical applications, to thereby enable others skilled in the art to best use the embodiments with various modifications as are suited to the particular uses contemplated.

What is claimed is:

1. A superconducting circuit, comprising:
a first component having a first end with a first width;
a second component having a second end with a second width, the second width different than the first width; and
an asymmetrically-tapered connector electrically connected to the first end of the first component with the second end of the second component, the asymmetrically-tapered connector comprising a set of asymmetrical tapered portions.

2. The superconducting circuit of claim 1, wherein the asymmetrically-tapered connector is composed of a superconducting material.

3. The superconducting circuit of claim 1, wherein the first component, the second component, and the asymmetrically-tapered connector are arranged on a same layer of material.

4. The superconducting circuit of claim 1, wherein the first component and the second component are superconducting components.

5. The superconducting circuit of claim 1, wherein the set of asymmetrical tapered portions comprises two or more tapered portions.

6. The superconducting circuit of claim 1, wherein the first component and the second component are formed from a same superconducting film.

7. The superconducting circuit of claim 1, wherein the set of asymmetrical tapered portions comprises a taper having a non-linear shape.

8. The superconducting circuit of claim 1, wherein the asymmetrically-tapered connector has a tapered edge and a straight edge opposite the tapered edge.

9. The superconducting circuit of claim 1, wherein the set of asymmetrical tapered portions comprises a first tapered portion and a second tapered portion, and wherein a first taper of the first tapered portion and a second taper of the second tapered portion have a same first derivative at a meeting point.

10. The superconducting circuit of claim 1, wherein the second component comprises a readout component, the readout component being configured to determine a state of the first component.

11. The superconducting circuit of claim 10, wherein determining the state of the first component comprises determining whether the first component is operating in a superconducting state or a non-superconducting state.

12. The superconducting circuit of claim 1, wherein the second component comprises a pad or via.

13. The superconducting circuit of claim 1, wherein the second component comprises at least one of an inductor, or a resistor.

14. The superconducting circuit of claim 1, wherein the first component is a photon detector component.
